(19) United States
(12) Patent Application Publication
(10) Pub. No.: US 2025/0385182 A1
(43) Pub. Date: Dec. 18, 2025

(54) BI-DIRECTIONAL REDISTRIBUTION LAYER (RDL) ROUTING

(71) Applicant: QUALCOMM Incorporated, San Diego, CA (US)

(72) Inventors: Narender GANJI, Hyderabad (IN); Harshavardhan Reddy DODLA, Hyderabad (IN); Pushpahas BHARADWAJ, Bahadurgarh (IN)

(21) Appl. No.: 18/742,985

(22) Filed: Jun. 13, 2024

(51) Int. Cl. H01L 23/528; H01L 23/00

(52) U.S. Cl. CPC H01L 23/5286; H01L 24/16; H01L 2224/16227

(57) ABSTRACT

A chip includes a bi-directional power routing structure in a redistribution layer. The bi-directional power routing structure includes a first elongated member extending in a first direction, a second elongated member extending from the first elongated member in a second direction perpendicular to the first direction, and first fingers extending from the second elongated member in the first direction. The chip also includes a bi-directional ground routing structure in the redistribution layer. The bi-directional ground routing structure includes a third elongated member extending in the first direction, a fourth elongated member extending from the third elongated member in the second direction, and second fingers extending from the fourth elongated member in the first direction, wherein the second fingers are interleaved with the first fingers.

### BACKGROUND

### FIELD

### Aspects of the present disclosure relate generally to chip layout and more particularly to mitigating current-resistance IR drops in a powerground distribution network

### BACKGROUND

A chip includes devices (e.g., active devices) and metal layers above the devices. The metal layers are patterned to provide signal routing for the devices. The metal layers are also patterned to form a power distribution network for distributing power (e.g., a supply voltage) to the devices. The metal layers are also patterned to form a ground network for providing the devices with a connection to a ground. The power distribution network and the ground network may be referred to collectively as a power/ground distribution network.

### SUMMARY

### The following presents a simplified summary of one or more implementations in order to provide a basic understanding of such implementations This summary is not an extensive overview of all contemplated implementations and is intended to neither identify key or critical elements of all implementations nor delineate the scope of any or all implementations Its sole purpose is to present some concepts of one or more implementations in a simplified form as a prelude to the more detailed description that is presented later

A first aspect relates to a chip. The chip includes a bi-directional power routing structure in a redistribution layer. The bi-directional power routing structure includes a first elongated member extending in a first direction, a second elongated member extending from the first elongated member in a second direction perpendicular to the first direction, and first fingers extending from the second elongated member in the first direction. The chip also includes a bi-directional ground routing structure in the redistribution layer. The bi-directional ground routing structure includes a third elongated member extending in the first direction, a fourth elongated member extending from the third elongated member in the second direction, and second fingers extending from the fourth elongated member in the first direction, wherein the second fingers are interleaved with the first fingers.

A second aspect relates to a chip. The chip includes a bi-directional ground routing structure in a redistribution layer. The bi-directional ground routing structure includes a first elongated member, first fingers extending from the first elongated member in a first direction, wherein the first elongated member extends in a second direction perpendicular to the first direction, and second fingers extending from the first elongated member in the first direction. The chip also includes a first bi-directional power routing structure in the redistribution layer. The first bi-directional power routing structure includes a second elongated member extending in the second direction, and third fingers extending from the second elongated member in the first direction, wherein the third fingers are interleaved with the first fingers. The chip also includes a second bi-directional power routing structure in the redistribution layer The second bi-directional power routing structure includes a third elongated member extending in the second direction, and fourth fingers extending from the third elongated member in the first direction, wherein the fourth fingers are interleaved with the second fingers.

### BRIEF DESCRIPTION OF THE DRAWINGS

FIG. 1 shows a side view of an example of a chip including an active device and multiple metal layers according to certain aspects of the present disclosure.

FIG. 2 shows a side view of a redistribution layer RDL and bumps coupled to the RDL according to certain aspects of the present disclosure.

FIG. 3 shows a side view of an array of bumps coupling the chip to an external substrate according to certain aspects of the present disclosure.

FIG. 4 shows an example of a power source coupled to the chip according to certain aspects of the present disclosure.

FIG. 5A shows a top view of an example of power routing structures and ground routing structures formed in a redistribution layer according to certain aspects of the present disclosure.

FIG. 5B shows a top view of an example of bumps on the power routing structures and the ground routing structures of FIG. 5A according to certain aspects of the present disclosure.

FIG. 6A shows a top view of an example of bi-directional power routing structures and bi-directional ground routing structures formed in a redistribution layer according to certain aspects of the present disclosure.

FIG. 6B shows a close-up view of a portion of the bi-directional power routing structures and the bi-directional ground routing structures of FIG. 6A according to certain aspects of the present disclosure.

FIG. 6C shows the close-up view of FIG. 6B without the bi-directional ground routing structures according to certain aspects of the present disclosure.

FIG. 6D shows the close-up view of FIG. 6B without the bi-directional power pouting structures according accrording to certain aspects of the present disclosure.

FIG. 6E shows a top view of an example of bumps on the bi-directional power routing structures and the bi-directional ground routing structures of FIG. 6A according to certain aspects of the present disclosure.

FIG. 7 shows an example of power rails and ground rails in a metal layer below the redistribution layer according to certain aspects of the present disclosure.

FIG. 8A shows an example of power vias disposed on the power rails and ground vias disposed on the ground rails according to certain aspects of the present disclosure.

FIG. 8B shows locations of the power vias and the ground vias relative to one of the bi-directional power routing structures and two of the bi-directional ground routing structures according to certain aspects of the present disclosure.

FIG. 9A shows a top view of an example of bi-directional power routing structures and bi-directional ground routing structures for multiple power domains according to certain aspects of the present disclosure.

FIG. 9B shows the top view of FIG. 9A without the bi-directional ground routing structures according to certain aspects of the present disclosure.

FIG. 9C shows the top view of FIG. 9A without the bi-directional power routing structures according to certain aspects of the present disclosure.

FIG. 9D shows a top view of an example of bumps on the bi-directional power routing structures and the bi-directional ground routing structures of FIG. 9A according to certain aspects of the present disclosure

FIG. 9E shows a close-up view of a portion of the bi-directional power routing structures and the bi-directional ground routing structures of FIG. 9A according to certain aspects of the present disclosure

FIG. 10 shows an exemplary layout of power vias and ground vias according to certain aspects of the present disclosure.

FIG. 11 shows an example of power rails and ground rails coupled to a subset of the power vias and the ground vias of FIG. 10 according to certain aspects of the present disclosure.

### DETAILED DESCRIPTION

### The detailed description set forth below in connection with the appended drawings is intended as a description of various configurations and is not intended to represent the only configurations in which the concepts described herein may be practiced The detailed description includes specific details for the purpose of providing a thorough understanding of the various concepts However it will be apparent to those skilled in the art that these concepts may be practiced without these specific details In some instances well-known structures and components are shown in block diagram form in order to avoid obscuring such concepts.

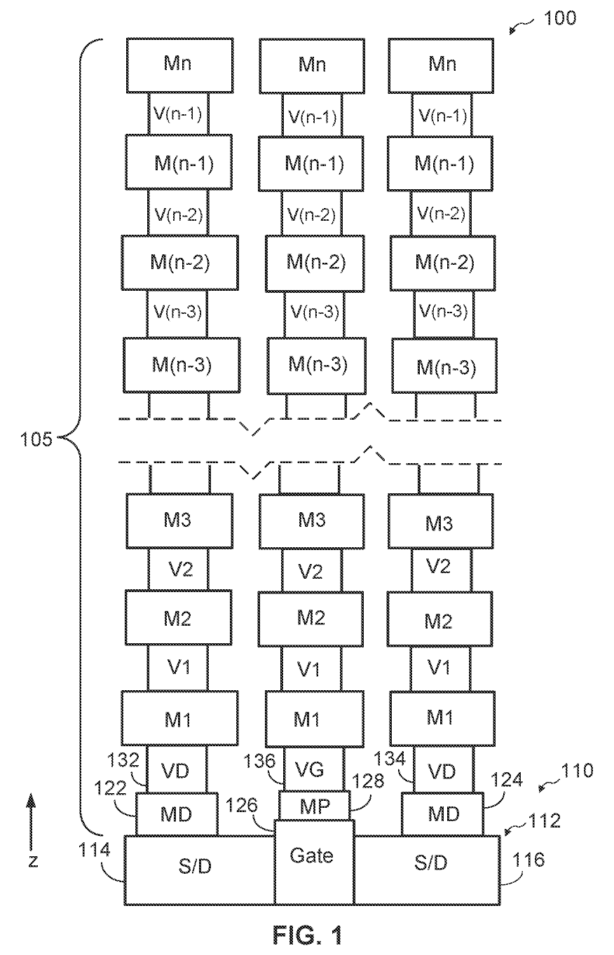

FIG. 1 shows a side view of an example of a chip 100 (e.g., a die) including an active device 110 (e.g., transistor) and multiple layers 105 according to certain aspects. The active device 110 may be formed in a front end of line (FEOL) of the chip 100 and the multiple layers 105 may be formed in a back end of line (BEOL) of the chip 100 above the FEOL. Although one active device 110 is shown in FIG. 1 for simplicity, it is to be appreciated that the chip 100 includes many active devices. For example, the chip 100 may implement a system on a chip (SoC) including many active devices. The active device 110 may be implemented using a planar process, a fin field-effect transistor (FinFET) process, a gate-all-around FET process, or another type of process.

In the example shown in FIG. 1, the active device 110 includes a diffusion region 112 and a gate 126 on the diffusion region 112. The diffusion region 112 may also be referred to as an oxide diffusion (OD) region, an active region, active diffusion, active (RX), active layer, or another term. The gate 126 may include polysilicon, one or more gate metals, and/or another gate material. In the example shown in FIG. 1, a portion of the diffusion region 112 to the left of the gate 126 provides a first source/drain 114 of the active device 110, and a portion of the diffusion region 112 to the right of the gate 126 provides a second source/drain 116 of the active device 110. As used herein, the term “source/drain” means a source, a drain, or both a source and a drain. In certain aspects, each of the first source/drain 114 and the second source/drain 116 may include epitaxially grown or deposited silicon, a silicon-based material (e.g., silicon-germanium), or any combination thereof.

In this example, the chip 100 includes a contact 122 coupled to the first source/drain 114, and a contact 124 coupled to the second source/drain 116. The contacts 122 and 124 may be formed (i.e., patterned) from a contact layer using, for example, lithographic and etching processes. Each contact 122 and 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations.

In this example, the layers 105 in the BEOL of the chip 100 include a stack of metal layers (labeled M1 to Mn in FIG. 1) stacked in the vertical direction (i.e., z direction in FIG. 1). The metal layers are patterned (e.g., using lithography and etching) to provide signal routing for the active device 110 and other active devices (not shown in FIG. 1) integrated on the chip 100. The metal layers are also patterned to form a power distribution network (also referred to as a power grid) for distributing power (e.g., a supply voltage) to the active device 110 and other active devices integrated on the chip 100. The metal layers are also patterned to form a ground network for providing the active device 110 and the other active devices with a ground connection. The power distribution network and the ground network may be referred to collectively as a power/ground distribution network.

In the example in FIG. 1, the metal layers include n metal layers where n is an integer. For example, the number of metal layers (i.e., n) may depend on the process node used to fabricate the chip 100. In the example shown in FIG. 1, the bottom-most metal layer is referred to as metal layer M1 and the top-most metal layer is referred to as metal layer Mn. However, it is to be appreciated that the present disclosure is not limited to the nomenclature in which the bottom-most metal layer is referred to as metal layer M1. For instance, in another example, the bottom-most metal layer may be referred to as metal layer M0 instead of metal layer M1. Also, it is to be appreciated that one or more of the metal layers may be designated with a letter other than M in other examples. Accordingly, it is to be appreciated that the metal layers are not limited to the exemplary designations used in FIG. 1.

In the example shown in FIG. 1, the metal layer above metal layer M1 is referred to as metal layer M2, the metal layer above metal layer M2 is referred to as metal layer M3, and so forth. Also, the metal layer below metal layer Mn is referred to as metal layer metal layer M(n-1), the metal layer below metal layer M(n-1) is referred to as metal layer M(n-2), the metal layer below metal layer M(n-2) is referred to as metal layer M(n-3), and so forth. It is to be appreciated that metal structures (e.g., signal paths, power rails, ground rails, etc.) in the metal layers M1 to Mn are not necessarily drawn to scale in FIG. 1. For example, metal structures in the upper metal layers (e.g., metal layers M(n-3) to Mn) may have wider widths and/or larger thicknesses than metal structures in the lower metal layers (e.g., metal layers M1 to M3). Also, it is to be appreciated that metal structures in the same metal layer may have different widths. For example, metal structures used for power routing (e.g., power rails) may have wider widths than metal structures used for signal routing in the same metal layer.

The layers 105 in the BEOL also include vias (labeled V1 to V(n-1)) that provide coupling between the metal layers. In this example, the vias V1 provide coupling between metal layer M1 and metal layer M2, the vias V2 provide coupling between metal layer M2 and metal layer M3, and so forth. Also, the vias V(n-1) provide coupling between metal layer M(n-1) and metal layer Mn, the vias V(n-2) provide coupling between metal layer M(n-2) and metal layer M(n-1), the vias V(n-3) provide coupling between metal layer M(n-3) and metal layer M(n-2), and so forth. In the example in FIG. 1, the chip 100 also includes a via 136 coupling the gate contact 128 to metal layer M1, a via 132 coupling the contact 122 for the first source/drain 114 to metal layer M1, and a via 134 coupling the contact 124 for the second source/drain 116 to metal layer M1.

In certain aspects, one or more metal structures (e.g., one or more power rails, one or more ground rails, or signal paths) in metal layer Mn may be coupled to one or more bumps (e.g., solder bumps). The one or more bumps may provide an external connection for the one or more metal structures. For example, the one or more bumps may be used to couple one or more power rails in metal layer Mn to an external power source (e.g., power management integrated circuit (PMIC)). In another example, the one or more bumps may be used to couple one or more ground rails in metal layer Mn to an external ground.

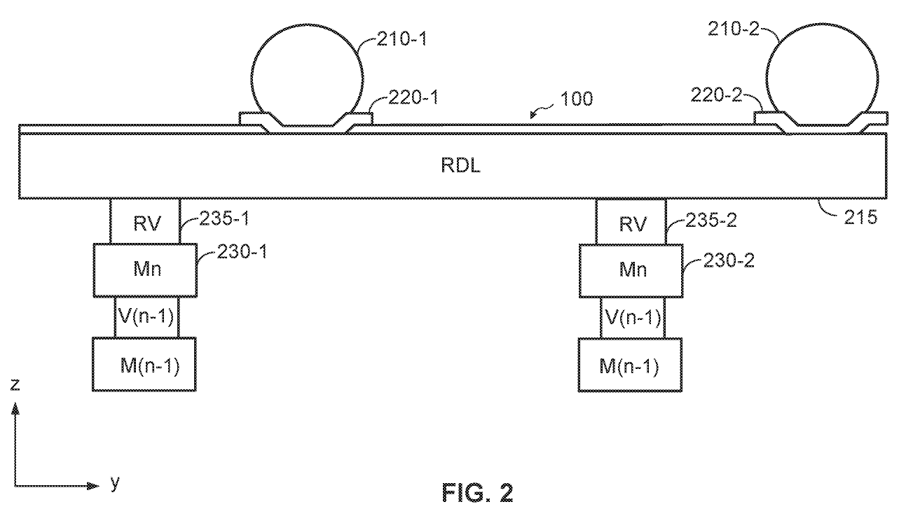

FIG. 2 shows an example of a side view of an example of a first metal rail 230-1 and a second metal rail 230-2 formed in metal layer Mn (e.g., using lithography and etching). The metal rails 230-1 to 230-2 may be power rails in a power distribution network or ground rails in a ground network. The metals rails 230-1 to 230-2 may be coupled to active devices in the FEOL of the chip 100 (e.g., the active device 110) through the metal layers M1 to M(n-1) below metal layer Mn.

FIG. 2 also shows an example of a first bump 210-1, a second bump 210-2, and a redistribution layer (RDL) 215 coupled to the first bump 210-1 and the second bump 210-2. As discussed further below, the RDL 215 provides routing for coupling the metal rails 230-1 and 230-2 to the bumps 210-1 and 210-2. In general, the RDL 215 provides metal routing between bumps (e.g., solder bumps) and metal layer Mn (i.e., the topmost metal layer of the stack of metal layers M1 to Mn). The RDL 215 is above metal layer Mn and may extend in the y direction shown in FIG. 2. The RDL 215 may also be referred to as the AP layer or another term. The RDL 215 may include aluminum and/or another type of metal.

In the example in FIG. 2, the chip 100 includes a first via 235-1 disposed between the first metal rail 230-1 and the RDL 215, and second via 235-2 disposed between the first metal rail 230-1 and the and RDL 215, and a second via 235-2 disposed between the second metal rail 230-2 and the RDL 215. In this example, the first metal rail 230-1 is coupled to the RDL 215 through the first via 235-1, and the second metal rail 230-2 is coupled to the RDL 215 through the second via 235-2.

In the example in FIG. 2, the chip 100 also includes a first bump pad 220-1 disposed between the first bump 210-1 and the RDL 215, and a second bump pad 220-2 disposed between the second bump 210-1 and the RDL 215. Thus, in this example, the RDL 215 is coupled to the first bump 210-1 through the first bump pad 220-1, and the RDL 215 is coupled to the second bump 210-2 through the second bump pad 220-2. Each of the bump pads 220-1 and 220-2 may include under bump metallurgy (UBM) and/or one or more other layers.

It is to be appreciated that the metal rails 230-1 and 230-2, the RDL 215, and the bumps 210-1 and 210-2 are not necessarily drawn to scale in FIG. 2.

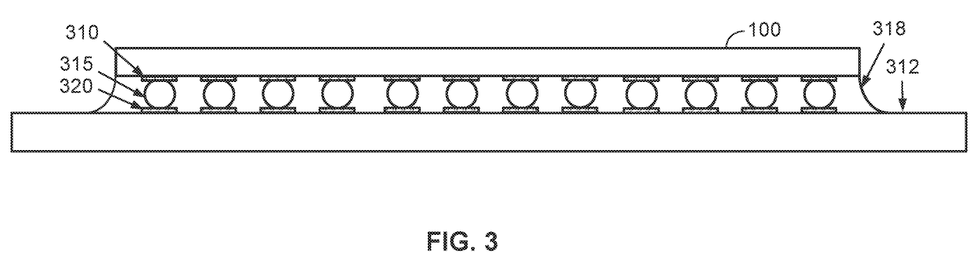

In certain aspects an array of bumps may be formed on the chip 100 to provide electrical connections to the chip 100 In this regard FIG. 3 shows an example of a side view of the chip 100 and an external substrate 312 according to certain aspects In this example the chip 100 is flip-chip mounted onto the substrate 312 with an array of bumps 315 eg solder bumps coupling bump pads 310 on the chip 100 to pads 320 on the substrate 312 The bumps 315 may include the exemplary bumps 210-1 and 210-2 shown in FIG. 2 The space between the chip 100 and the substrate 312 may be filled with an underfill 318 eg a resin It is to be appreciated that the chip 100 the pads 310 and 320 and the bumps 315 are not necessarily drawn to scale in FIG. 3.

In certain aspects the substrate 312 may be the substrate of a package mounted on a printed circuit board not shown In this example the substrate 312 may include metal routing not shown coupling the bumps 315 to metal traces on andor embedded in the printed circuit board PCB The metal traces may couple the bumps 315 to one or more external circuits which may also be mounted on the PCB an external power source external ground etc In certain aspects the substrate 312 may be the substrate of a silicon interposer eg for a multichip package in which the silicon interposer couples the bumps 315 to the package substrate.

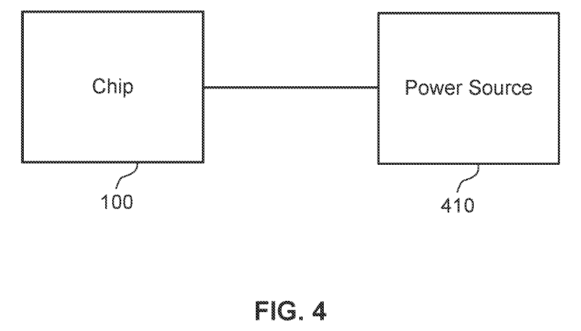

FIG. 4 shows an example of the chip 100 coupled to a power source 410 according to certain aspects. The power source 410 may be coupled to one or more power distribution networks in the chip 100 through one or more of the bumps 315 (shown in FIG. 3) and metal routing in the substrate 312. The power source 410 may be configured to provide each of the power distribution networks in the chip 100 with a supply voltage. The power source 410 may be implemented with a power management integrated circuit (PMIC), which may include one or more voltage regulators configured to generate one or more supply voltages. The one or more regulators may include one or more DC/DC converters, one or more low dropout (LDO) regulators, one or more switching regulators, etc.

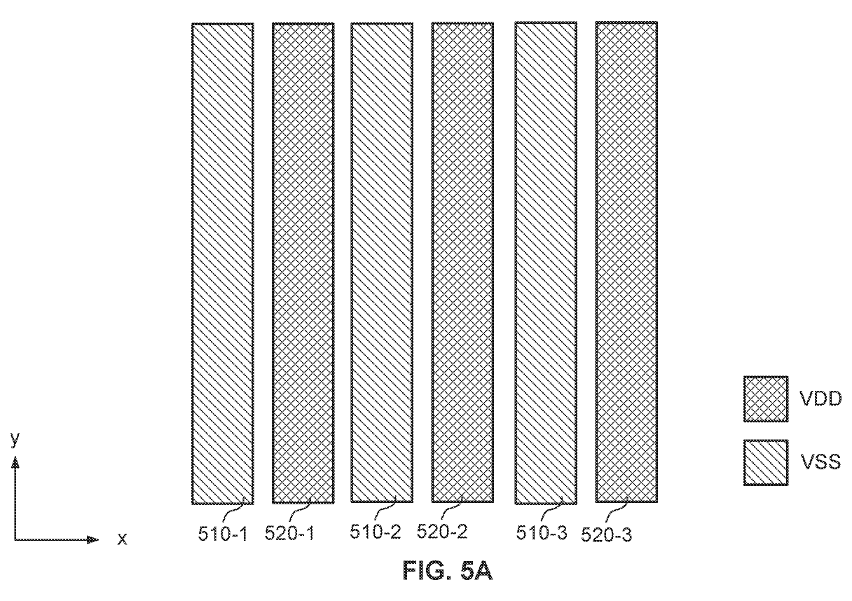

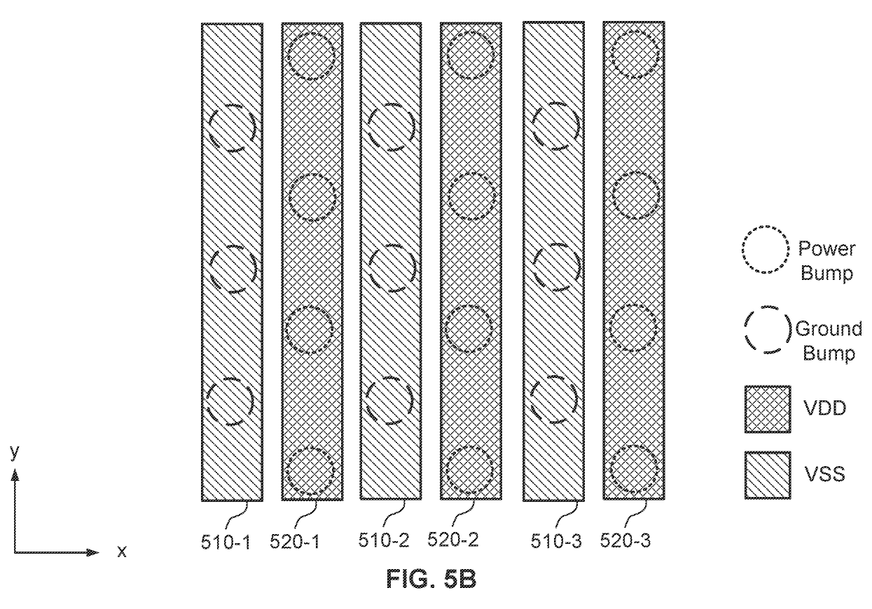

FIG. 5A shows a top view of an example of ground routing structures 510-1, 510-2, and 510-3 and power routing structures 520-1, 520-2, and 520-3 formed in the redistribution layer (RDL) (e.g., RDL 215) according to certain aspects. The ground routing structures 510-1, 510-2, and 510-3 provide routing between a ground network (e.g., ground mesh) formed in metal layer Mn and bumps on the chip 100, where metal layer Mn is underneath the RDL. The ground routing structures 510-1, 510-2, and 510-3 are coupled to the ground network in metal layer Mn by vias (e.g., RV vias in FIG. 2) disposed between the ground network in metal layer Mn and the ground routing structures 510-1,510-2, and 510-3. In FIG. 5A, ground is labeled VSS.

The power routing structures 520-1, 520-3, and 520-3 provide power routing between a power network (e.g., power mesh) formed in metal layer Mn and bumps on the chip 100. The power routing structures 520-1, 520-2, and 520-3 are coupled to the power network in metal layer Mn by vias (e.g., RV vias in FIG. 2) disposed between the power network in metal layer Mn and the power routing structures 520-1, 520-2, and 520-3.

In this example, the ground routing structures 510-1, 510-2, and 510-3 and the power routing structures 520-1,520-2, and 520-3 are unidirectional in that each of the ground routing structures 510-1, 510-2, and 510-3 and each of the power routing structures 520-1, 520-2, and 520-3 extends in the y direction in FIG. 5A. In the example shown in FIG. 5A, the ground routing structures 510-1, 510-2, and 510-3 and the power routing structures 520-1, 520-2, and 520-3 are laid out in an alternating fashion in the x direction, where the x direction is perpendicular to the y direction. In this example, the power routing structure 520-1 is between the ground routing structures 510-1 and 510-2 in the x direction, and the power routing structure 520-2 is between the ground routing structures 510-2 and 510-3 in the x direction.

FIG. 5B shows a top view of an exemplary layout of power bumps for the power routing structures 520-1, 520-2, and 520-3, and ground bumps for the ground routing structures 510-1, 510-2, and 510-3. In FIG. 5B, each of the power bumps is shown with a dotted line, and each of the ground bumps is shown with a dashed line. Each of the power bumps and each of the ground bumps may be an instance of one of the bumps 210-1 and 210-2 shown in FIG. 2. In the example shown in FIG. 5B, the power bumps and the ground bumps are staggered in the y direction. In this example, the power routing structures 520-1, 520-2, and 520-3 may be coupled to a power source (e.g., the power source 410) through the power bumps, and the ground routing structures 510-1, 510-2, and 510-3 may be coupled to an external ground through the ground bumps. In certain aspects, each of the power bumps may be coupled to one of the power routing structures 520-1, 520-2, 520-3 through a respective bump pad (not shown in FIG. 5B), and each of the ground bumps may be coupled to one of the ground routing structures 510-1, 510-2, 510-3 through a respective bump pad (not shown in FIG. 5B).

The chip 100 may include an integrated circuit that draws a large amount of current. For example, the circuit may include a processor (e.g., a central processing unit CPU), a memory, or any combination thereof. In this example, the circuit may need to draw a large amount of current in order to run at a high frequency for high performance. The large amount of current may generate large IR drops in the power/ground distribution network, which lowers the operating voltage of the circuit. The lower operating voltage reduces the maximum frequency at which the circuit can operate, and hence reduces performance. In addition, the large IR drops reduce the power efficiency of the power/ground distribution network by increasing the amount of power that is dissipated in the power/ground distribution network (i.e., reducing the amount of power that is delivered to the circuit). Accordingly, it is desirable to reduce IR drops in the power/ground distribution network to increase the operating voltage of the circuit (e.g., processor) and improve the power efficiency of the power/ground distribution network.

The layout of the ground routing structures 510-1, 510-2, and 510-3 and the power routing structures 520-1, 520-2, and 520-3 shown in FIGS. 5A and 5B present challenges in reducing IR drops in the power/ground distribution network. For example, the power routing structures 520-1, 520-2, and 520-3 are spaced apart in the x direction by the ground routing structures 510-2 and 510-3. The large spaces between the power routing structures 520-1, 520-2, and 520-3 result in sparser via contacts to metal layer Mn, which increases IR drops between the power routing structures 520-1, 520-2, and 520-3 and metal layer Mn. In addition, the large spaces between the power routing structures 520-1, 520-2, and 520-3 may require that the power distribution network include additional routing at lower metal layers in order to route power to regions of the circuit (i.e., the processor) located below the spaces between the power routing structures 520-1, 520-2, and 520-3. The additional routing at the lower metal layers (which may have higher resistances) increases IR drops.

Similarly, the ground routing structures 510-1, 510-2, and 510-3 are spaced apart in the x direction by the power routing structures 520-1 and 520-2. The large spaces between the ground routing structures 510-1, 510-2, and 510-3 result in sparser via contacts to metal layer Mn, which increases IR drops between the ground routing structures 510-1, 510-2, and 510-3 and metal layer Mn. In addition, the large spaces between the ground routing structures 510-1, 510-2, and 510-3 may require that the ground network include additional routing at lower metal layers in order to provide ground routing for regions of the circuit (i.e., the processor) located below the spaces between the ground routing structures 510-1,510-2, and 510-3. The additional routing at the lower metal layers (which may have higher resistances) increases IR drops.

To address the above, aspects of the present disclosure provide bi-directional power routing structures and bi-directional ground routing structures in the RDL. The bi-directional routing structures facilitate more even distributions of via contacts to metal layer Mn (which reduce IR drops between the RDL and metal layer Mn) and provide for more effective utilization of RDL resources for power routing and ground routing. In some implementations, a bi-directional power routing structure includes fingers and a bi-directional ground routing structure includes fingers that are interleaved (i.e., interdigitated) with the fingers of the bi-directional power routing structure. The above features and other features of the present disclosure are discussed further below.

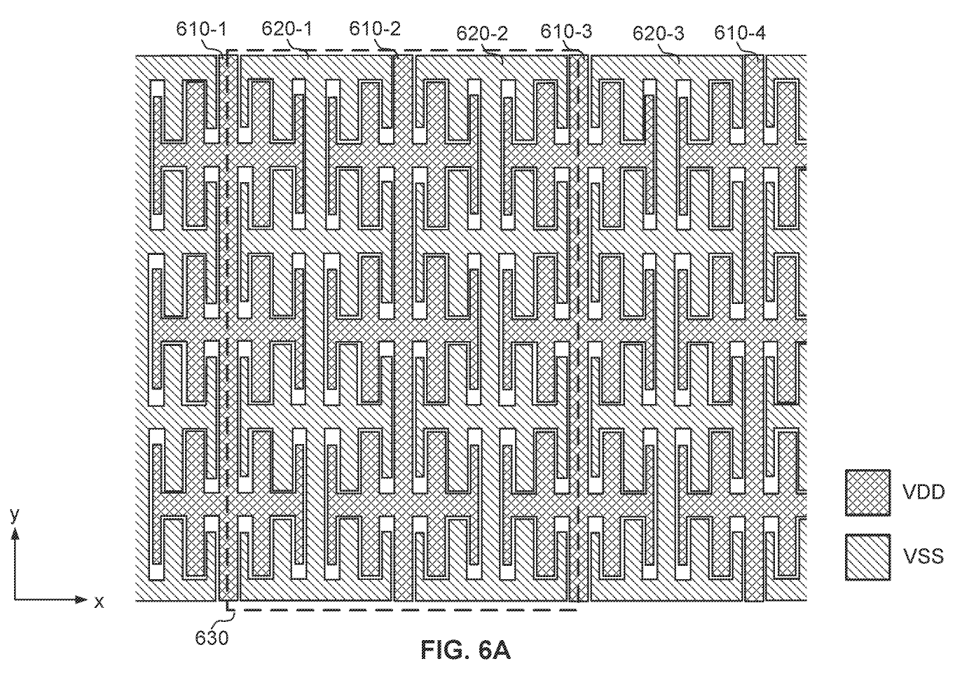

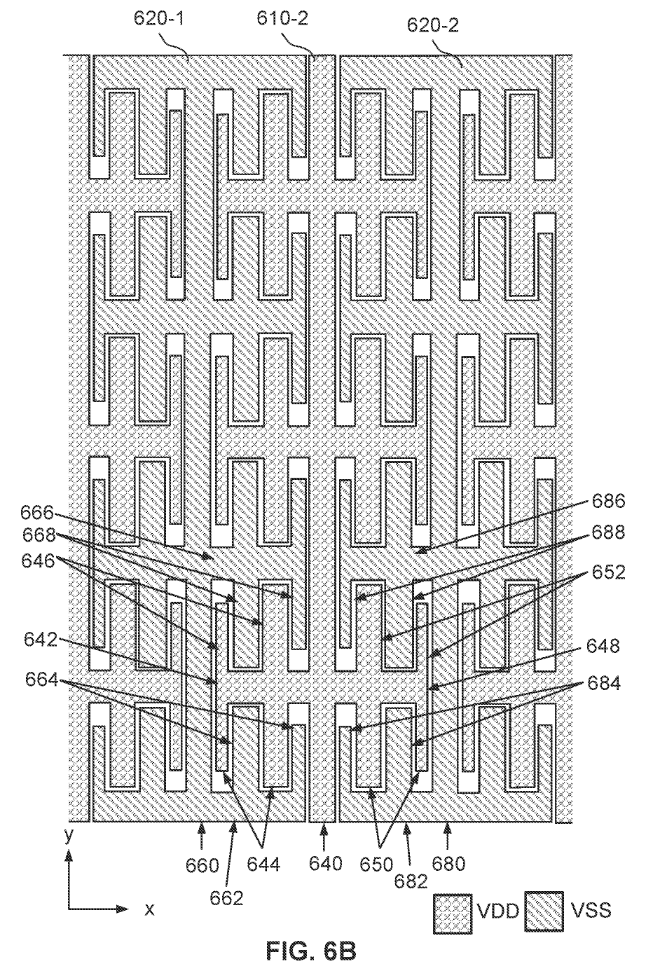

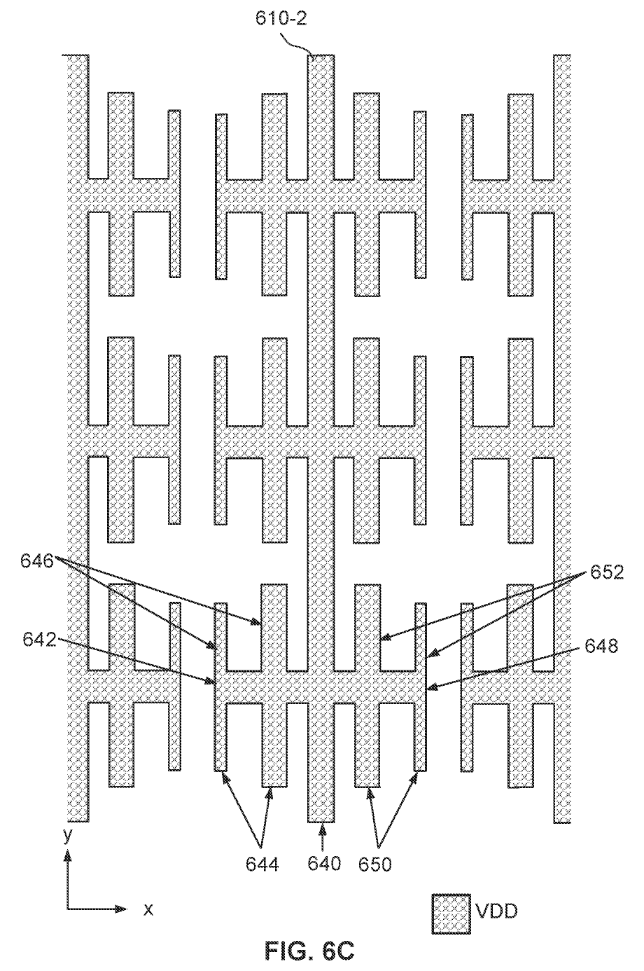

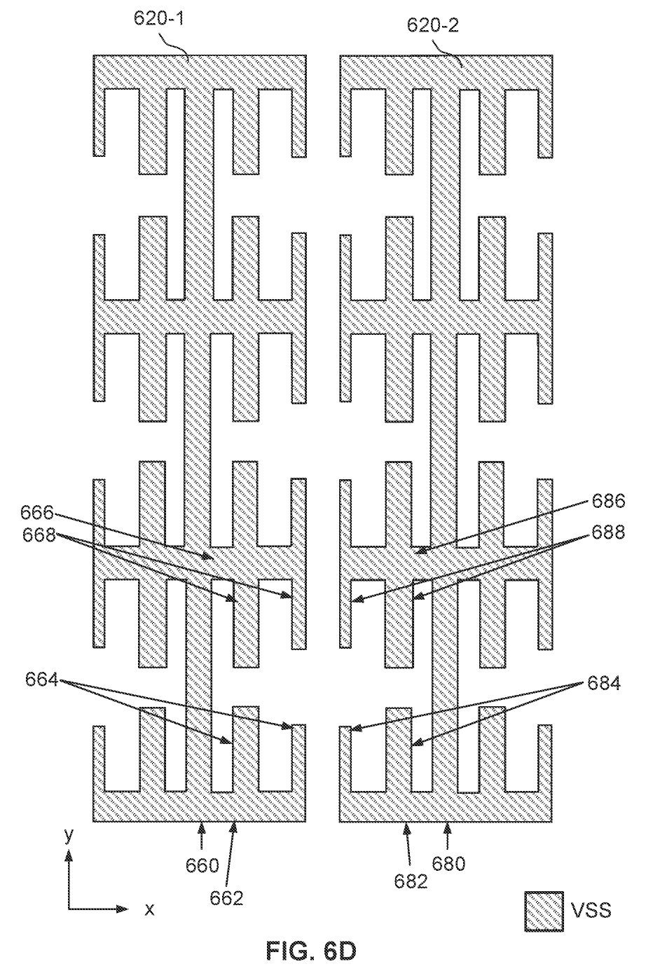

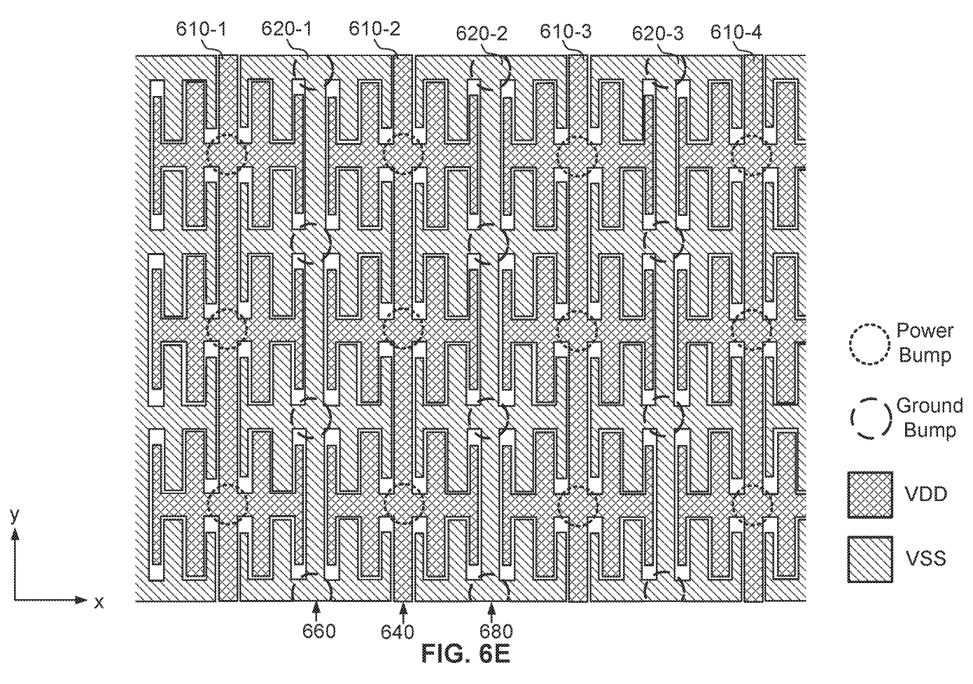

FIG. 6A shows a top view of an exemplary layout of bi-directional power routing structures 610-1 610-2 610-3 and 610-4 and bi-directional ground routing structures 620-1 620-2 and 620-3 according to certain aspects of the present disclosure The bi-directional power routing structures 610-1 610-2 610-3 and 610-4 and the bi-directional ground routing structures 620-1620-2 and 620-3 are formed in the RDL between the bumps and metal layer Mn eg using lithography and etching In the example shown in FIG. 6A each of the bi-directional power routing structures 610-1 610-2 610-3 and 610-4 and each of the bi-directional ground routing structures 620-1 620-2 and 620-3 extends in both the y direction and the x direction In contrast the ground routing structures 510-1 510-2 and 510-3 and the power routing structures 520-1520-2 and 520-3 in FIG. 5A are unidirectional.

In this example the bi-directional power routing structures 610-1 610-2 610-3 and 610-4 include fingers and the bi-directional ground routing structures 620-1 620-2 and 620-3 include fingers in which the fingers of the bi-directional power routing structures 610-1 610-2 610-3 and 610-4 are interleaved ie interdigitated with the fingers of the bi-directional ground routing structures 620-1620-2 and 620-3 This arrangement allows the vias between the bi-directional power routing structures 610-1 610-2610-3 and 610-4 and metal layer Mn and the vias between the bi-directional ground routing structures 620-1 620-2 and 620-3 and metal layer Mn to be more evenly distributed as discussed further below.

FIG. 6B shows a close-up view of the bi-directional power routing structure 610-2 and the bi-directional ground routing structures 620-1 and 620-2 located within the area 630 indicated in FIG. 6A according to certain aspects of the present disclosure FIG. 6C shows the close-up view of FIG. 6B without the bi-directional ground routing structures 620-1 and 620-2 and FIG. 6D shows the close-up view of FIG. 6B without the bi-directional power routing structure 610-2

In this example the bi-directional power routing structure 610-2 includes a first elongated member 640 extending in the y direction and a second elongated member 642 extending ie protruding from the first elongated member 640 in the x direction The bi-directional power routing structure 610-2 also includes first fingers 644 extending from the second elongated member 642 in the y direction in which the first fingers 644 are spaced apart in the x direction As used herein a “finger” is an elongated portion of a structure that extend from another portion of the structure An elongated member extends in the lengthwise direction.

The bi-directional ground routing structure 620-1 includes a third elongated member 660 extending in the y direction and a fourth elongated member 662 extending from the third elongated member 660 in the x direction The bi-directional ground routing structure 620-1 also includes second fingers 664 extending from the fourth elongated member 662 in the y direction in which the second fingers 664 are spaced apart in the x direction.

As shown in FIG. 6B the first fingers 644 of the bi-directional power routing structure 610-2 are interleaved ie interdigitated with the second fingers 664 of the bi-directional ground routing structure 620-1 Vias for the bi-directional power routing structure 610-2 to metal layer Mn may be placed under the first fingers 644 and vias for the bi-directional ground routing structure 620-1 to metal layer Mn may be placed under the second fingers 664 In this example the interleaving of the fingers 644 and 664 allows the vias for the bi-directional power routing structure 610-2 and the vias for the bi-directional ground routing structure 620-1 to be more evenly distributed compared with the layout in FIG. 5A.

In the example in FIG. 6B the bi-directional power routing structure 610-2 also includes third fingers 646 extending from the second elongated member 642 The third fingers 646 and the second fingers 664 extend from opposite sides of the second elongated member 642 In this example the bi-directional ground routing structure 620-1 includes a fifth elongated member 666 extending from the third elongated member 660 in the x direction The bi-directional ground routing structure 620-1 also includes fourth fingers 668 extending from the fifth elongated member 666 in the y direction in which the fourth fingers 668 are spaced apart in the x direction.

As shown in FIG. 6B the third fingers 646 of the bi-directional power routing structure 610-2 are interleaved ie interdigitated with the fourth fingers 668 of the bi-directional ground routing structure 620-1 Vias for the bi-directional power routing structure 610-2 to metal layer Mn may be placed under the third fingers 646 and vias for the bi-directional ground routing structure 620-1 to metal layer Mn may be placed under the fourth fingers 668.

In this example the bi-directional power routing structure 610-2 includes a sixth elongated member 648 extending from the first elongated member 640 in the x direction The sixth elongated member 648 and the second elongated member 642 extend from opposite sides of the first elongated member 640 in this example The bi-directional power routing structure 610-2 also includes fifth fingers 650 extending from the sixth elongated member 648 in the y direction in which the fifth fingers 650 are spaced apart in the x direction.

The bi-directional ground routing structure 620-2 includes a seventh elongated member 680 extending in the y direction and an eighth elongated member 682 extending from the seventh elongated member 680 in the x direction The bi-directional ground routing structure 620-2 also includes sixth fingers 684 extending from the eighth elongated member 682 in the y direction in which the sixth fingers 684 are spaced apart in the x direction.

As shown in FIG. 6B the fifth fingers 650 of the bi-directional power routing structure 610-2 are interleaved ie interdigitated with the sixth fingers 684 of the bi-directional ground routing structure 620-2 Vias for the bi-directional power routing structure 610-2 to metal layer Mn may be placed under the fifth fingers 650 and vias for the bi-directional ground routing structure 620-2 to metal layer Mn may be placed under the sixth fingers 684.

In the example in FIG. 6B the bi-directional power routing structure 610-2 also includes seventh fingers 652 extending from the sixth elongated member 648 The seventh fingers 652 and the fifth fingers 650 extend from opposite sides of the sixth elongated member 648 In this example the bi-directional ground routing structure 620-2 includes a ninth elongated member 686 extending from the seventh elongated member 680 in the x direction The bi-directional ground routing structure 620-2 also includes eighth fingers 688 extending from the ninth elongated member 686 in the y direction in which the eighth fingers 688 are spaced apart in the x direction.

As shown in FIG. 6B the seventh fingers 652 of the bi-directional power routing structure 610-2 are interleaved ie interdigitated with the eighth fingers 688 of the bi-directional ground routing structure 620-2 Vias for the bi-directional power routing structure 610-2 to metal layer Mn may be placed under the seventh fingers 652 and vias for the bi-directional ground routing structure 620-2 to metal layer Mn may be placed under the eighth fingers 688.

FIG. 6E shows a top view of an exemplary layout of power bumps for the bi-directional power routing structures 610-1 610-2 610-3 and 610-4 and ground bumps for the bi-directional ground routing structures 620-1620-2 and 620-3 In FIG. 6E each of the power bumps is shown with a dotted line and each of the ground bumps is shown with a dashed line Each of the power bumps and each of the ground bumps may be an instance of one of the bumps 210-1 and 210-2 shown in FIG. 2 As used herein a “power bump” is a bump configured to provide one or more supply voltages from a power source eg the power source 410 and a “ground bump” is a bump configured to provide a ground connection.

In the example shown in FIG. 6E the power bumps and the ground bumps are staggered in the y direction In this example the bi-directional power routing structures 610-1 610-2 610-3 and 610-4 may be coupled to a power source eg the power source 410 through the power bumps and the bi-directional ground routing structures 620-1 620-2 and 620-3 may be coupled to an external ground through the ground bumps In certain aspects each of the power bumps may be coupled to one of the power routing structures 610-1 610-2 610-3 and 610-4 through a respective bump pad not shown in FIG. 6E and each of the ground bumps may be coupled to one of the ground routing structures 620-1 620-2 and 620-3 through a respective bump pad not shown in FIG. 6E.

In the example shown in FIG. 6E, the power bumps for the bi-directional power routing structure 610-2 are aligned in the x direction and overlap the first elongated member 640 of the bi-directional power routing structure 610-2. Also, in this example, the ground bumps for the bi-directional ground routing structure 620-1 are aligned in the x direction and overlap the third elongated member 660 of the bi-directional ground routing structure 620-1. Further, the ground bumps for the bi-directional ground routing structure 620-2 are aligned in the x direction and overlap the seventh elongated member 680 of the bi-directional ground routing structure 620-2.

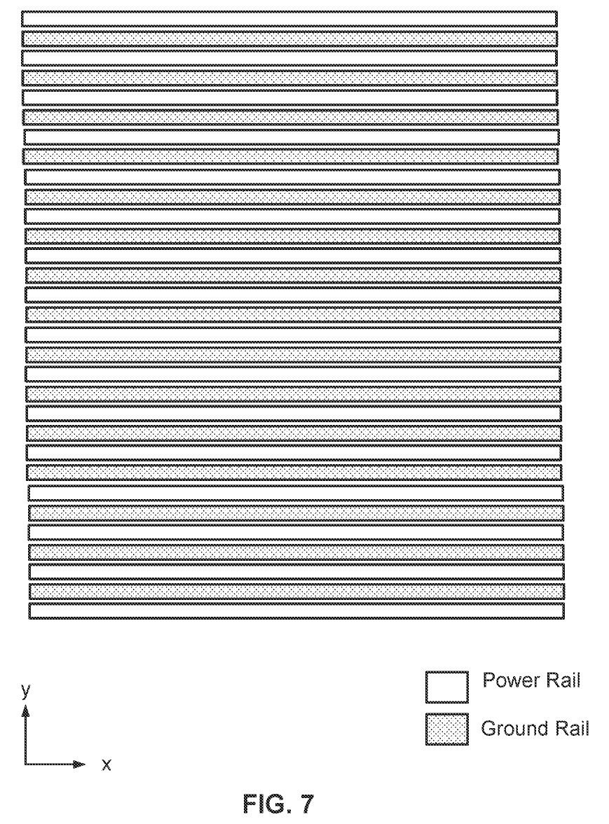

FIG. 7 shows an example of power rails and ground rails formed in metal layer Mn for power routing and ground routing respectively In this example each of the power rails and each of the ground rails is unidirectional and extends in the x direction However it is to be appreciated that the present disclosure is not limited to this example.

In the example in FIG. 7, the layout in metal layer Mn alternates between the power rials and ground rails. However, it is to be appreciated that the present disclosure is not limited to this example. In some implementations, the layout may include a power rail and a ground rail in the same row in which the power rail extends in the x direction across a first portion of the row and the ground rail extends in the x direction across a second portion of the row. Accordingly, it is to be appreciated that the present disclosure is not limited to a particular layout for the power rails and the ground rails in metal layer Mn, and that FIG. 7 shows an example of one possible layout.

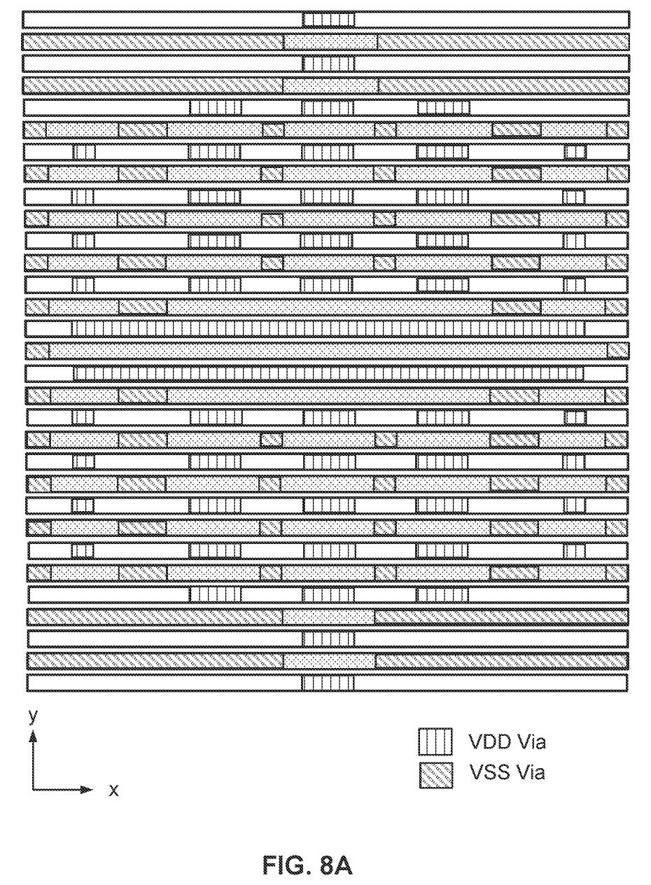

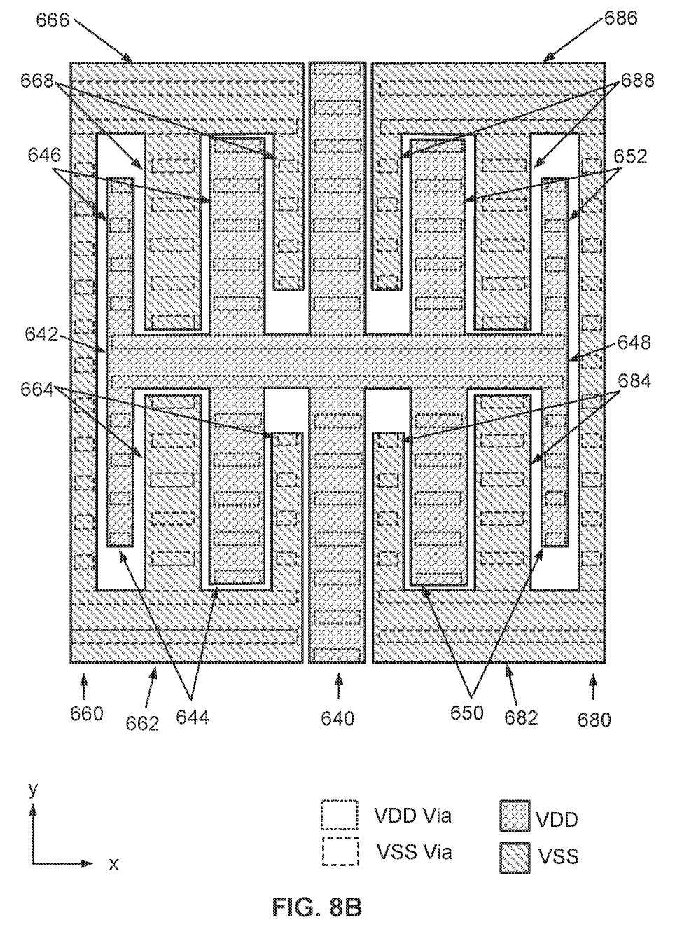

FIG. 8A shows an exemplary layout of power vias (labeled VDD vias) disposed on the power rails of FIG. 7 and ground vias (labeled VSS vias) disposed on the ground rails of FIG. 7. Each of the power vias is coupled between the respective one of the power rails and one of the power routing structures 610-1, 610-2, 610-3, and 610-4 (shown in FIGS. 6A to 6F), and each of the ground vias is coupled between the respective one of the ground rails and one of the ground routing structures 620-1, 620-2, and 620-3 (shown in FIGS. 6A to 6F). As shown in the example in FIG. 8A, interleaving the fingers of the power routing structures 610-1, 610-2, 610-3, and 610-4 with the fingers of the ground routing structures 620-1, 620-2, and 620-3 allows for a more even distribution of the power vias and the ground vias, which helps reduce IR drops.

It is to be appreciated that the power vias and the ground vias are not limited to the exemplary distribution pattern shown in FIG. 8A, and that the power vias and the ground vias may have shapes that differ from the exemplary shapes shown in FIG. 8A.

FIG. 8B shows a top view of a portion of the power routing structure 610-2 and portions of the ground routing structure 620-1 and 620-2. In FIG. 8B, the power vias of FIG. 8A are shown in dotted line to show the locations of the power vias in the x direction and the y direction relative to the power routing structure 610-2. Each of the power vias is disposed between the respective power rail in metal layer Mn (shown in FIG. 8A) and the power routing structure 610-2 to couple the respective power rail to the power routing structure.

In FIG. 8B, the ground vias of FIG. 8A are shown in dashed line to show the locations of the ground vias in the x direction and the y direction relative to the ground routing structures 620-1 and 620-2. Each of the ground vias is disposed between the respective ground rail in metal layer Mn (shown in FIG. 8A) and the respective one of the ground routing structures 620-1 and 620-2.

As shown in FIG. 8B, the power vias include power vias disposed between the first fingers 644 and the respective power rails in metal layer M1 (shown in FIG. 8A), power vias disposed between the third fingers 646 and the respective power rails in metal layer M1 (shown in FIG. 8A), power vias disposed between the fifth fingers 650 and the respective power rails in metal layer M1 (shown in FIG. 8A), and power vias disposed between the seventh fingers 652 and the respective power rails in metal layer M1 (shown in FIG. 8A).

Also, as shown in FIG. 8B, the ground vias include ground vias disposed between the second fingers 664 and the respective ground rails in metal layer M1 (shown in FIG. 8A), ground vias disposed between the fourth fingers 668 and the respective ground rails in metal layer M1 (shown in FIG. 8A), ground vias disposed between the sixth fingers 684 and the respective ground rails in metal layer M1 (shown in FIG. 8A), and ground vias disposed between the eighth fingers 688 and the respective ground rails in metal layer M1 (shown in FIG. 8A).

In the example shown in FIGS. 8A and 8B, the power vias coupled to the first fingers 644 are staggered (i.e., shifted) with respect to the ground vias coupled to the second fingers 664 in the y direction. This is because the power rails and the ground rails (which are coupled to the power vias and the ground vias, respectively) are offset from each other in the y direction in this example. However, it is to be appreciated that the present disclosure is not limited to this example.

Also, in the example shown in FIGS. 8A and 8B, the power vias coupled to the third fingers 646 are staggered (i.e., shifted) with respect to the ground vias coupled to the fourth fingers 668 in the y direction, the power vias coupled to the fifth fingers 650 are staggered (i.e., shifted) with respect to the ground vias coupled to the sixth fingers 684 in the y direction, and the power vias coupled to the seventh fingers 652 are staggered (i.e., shifted) with respect to the ground vias coupled to the eighth fingers 688 in the y direction. However, it is to be appreciated that the present disclosure is not limited to this example.

The interleaving of the bi-directional power routing structures (e.g., bi-directional power routing structures 610-1, 610-2, 610-3, and 610-4) with the bi-directional ground routing structures (e.g., bi-directional ground routing structures 620-1, 620-2, and 620-3) reduces the power/ground distribution network length and resistance compared with the routing approach illustrated in FIG. 5A. The bi-directional routing approach according to aspects of the present disclosure may also be applied to multi-power domain scenarios (e.g., multiple supply voltages), and may improve connectivity near general-purpose input/output (GPIO), peripheral bumps, and void regions especially at an edge of the chip (e.g., system on a chip (SoC)). Effective power/ground distribution in the top layer(s) facilitate faster turn-around times by reducing RDL iterations required for IR closure. The bi-directional routing approach according to aspects of the present disclosure may also provide more track availability for signal routing in the lower layers with an additional IR gain (e.g., 1% IR gain) and higher frequency operation.

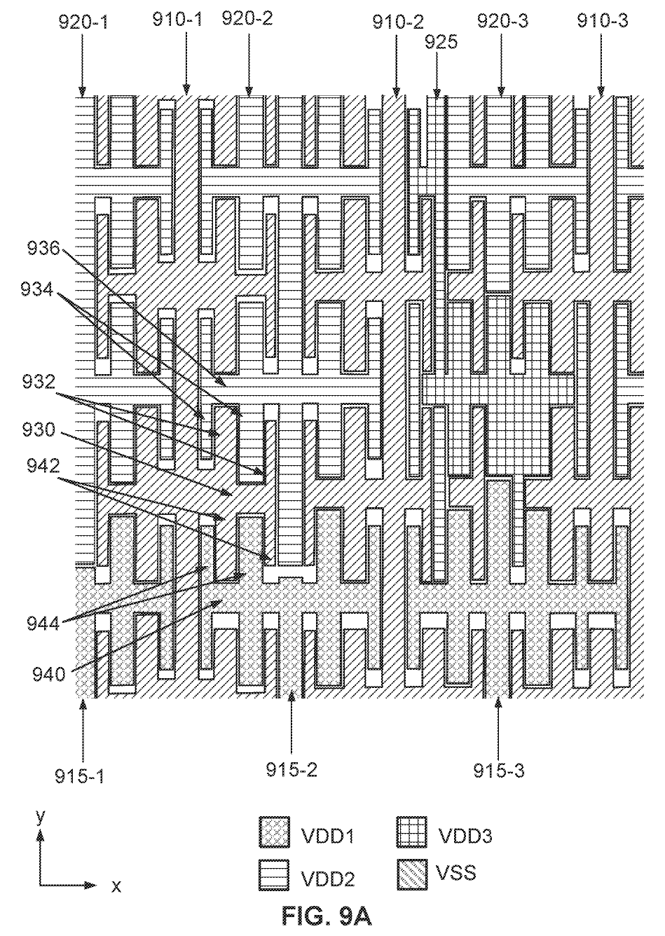

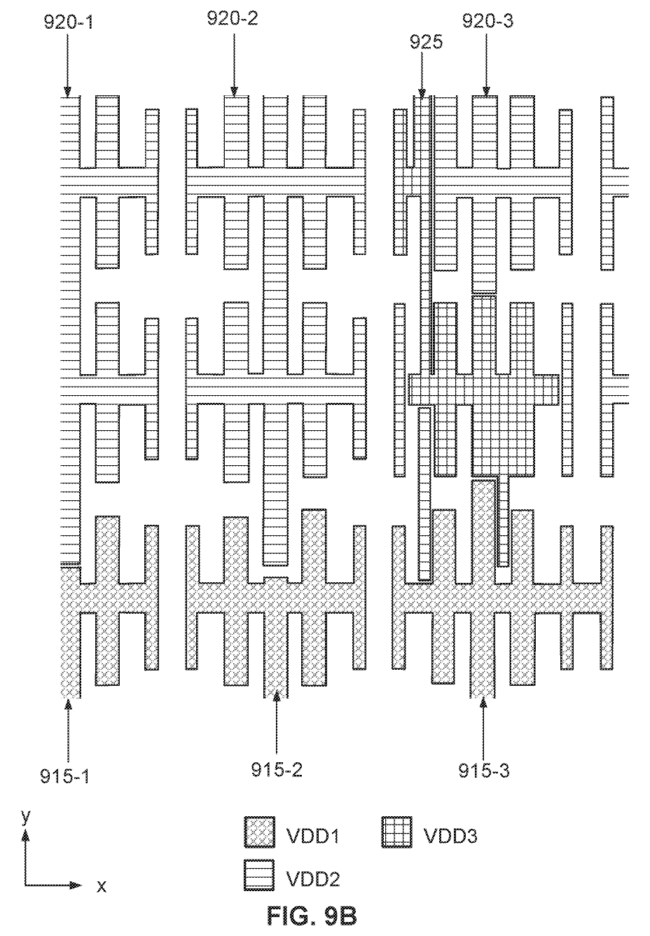

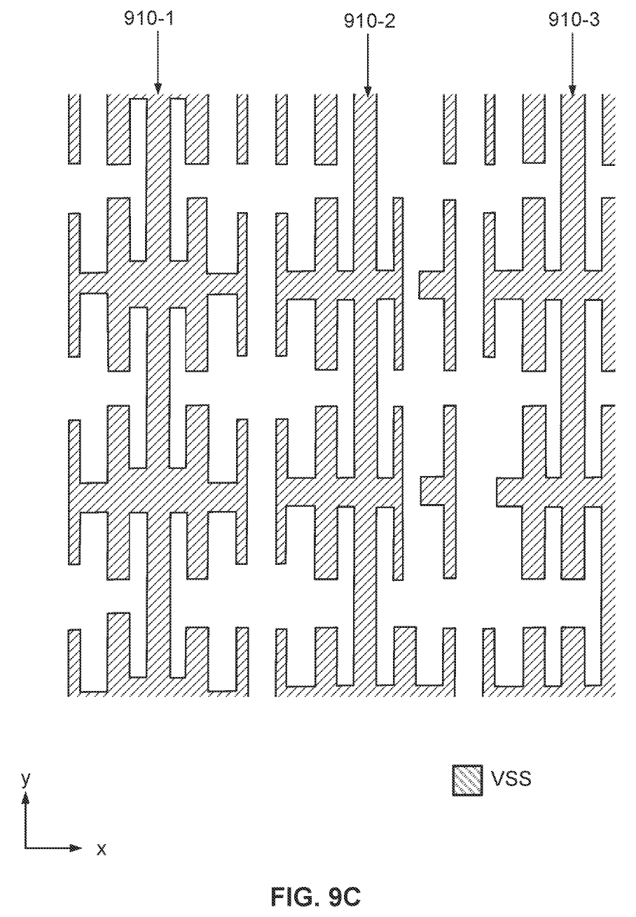

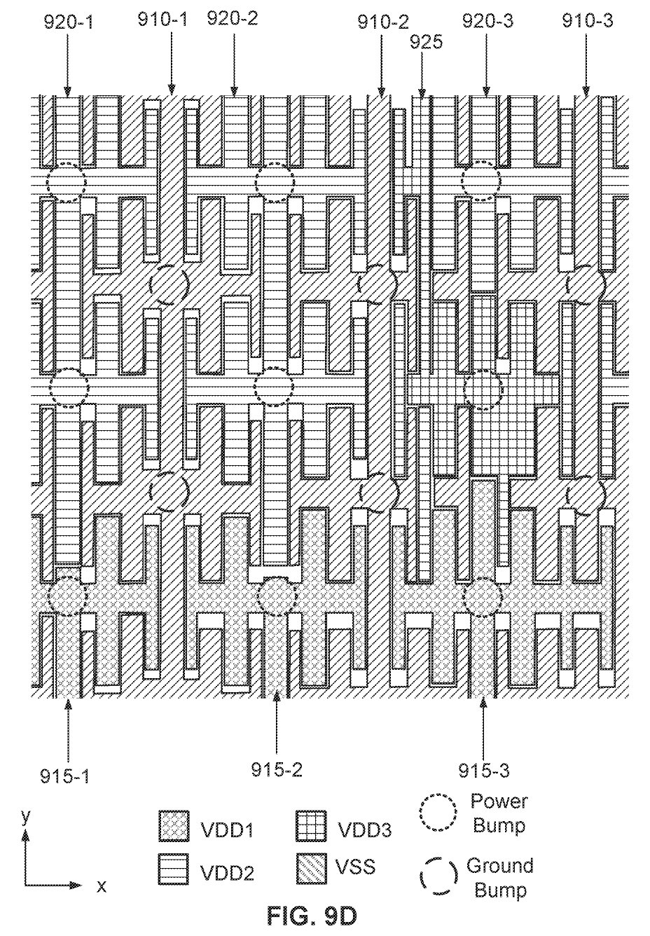

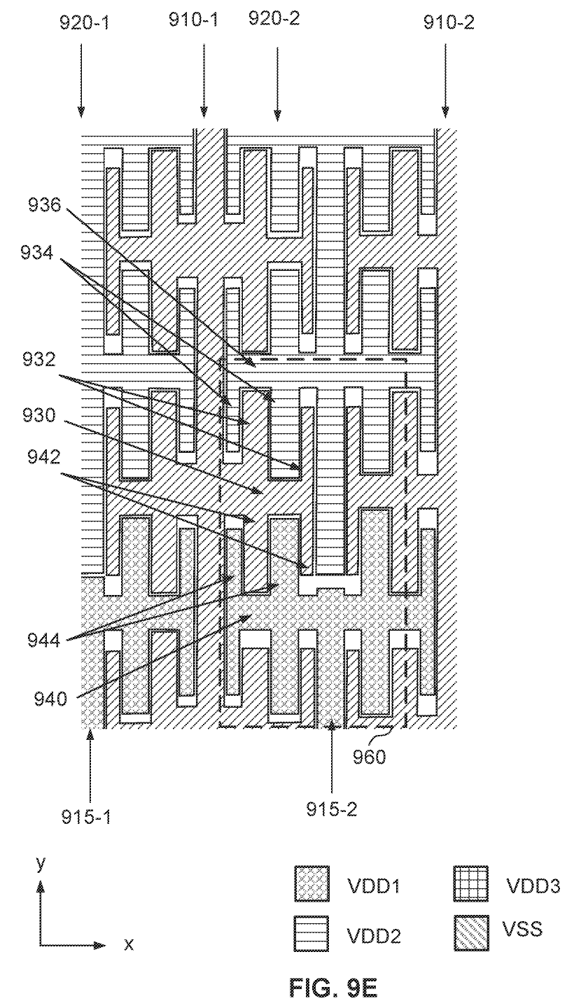

As discussed above, aspects of the present disclosure may be applied to multi-power domain scenarios. In this regard, FIG. 9A shows a top view of an exemplary layout of bi-directional power routing structures formed in the RDL for multiple power domains (also referred to as voltage domains). In this example, the bi-directional routing structures includes bi-directional power routing structures 915-1, 915-2, and 915-3 for a first power domain, bi-directional power routing structures 920-1,920-2, and 920-3 for a second power domain, and a bi-directional power routing structure 925 for a third power domain. Each of the power domains may have a different supply voltage.

In this example, the chip may include multiple circuits (e.g., sub systems) where each of the circuits operates in one of the power domains. In this example, the bi-directional power routing structures 915-1, 915-2, and 915-3 for the first power domain may route a first supply voltage VDD1 to a first power distribution network formed in the metal layers M1 to Mn for distributing power to circuits in the first power domain. The bi-directional power routing structures 920-1, 920-2, and 920-3 for the second power domain may route a second supply voltage VDD2 to a second power distribution network formed in the metal layers M1 to Mn for distributing power to circuits in the second power domain. The bi-directional power routing structure 925 for the third power domain may route a third supply voltage VDD3 to a third power distribution network formed in metal layers M1 to Mn for distributing power to circuits in the third power domain.

FIG. 9A also shows an exemplary layout of bi-directional ground routing structures 910-1, 910-2, and 910-3 formed in the RDL. The bi-directional ground routing structures 910-1, 910-2, and 910-3 may be coupled to a ground distribution network formed in the metal layers M1 to Mn. The ground distribution network may provide a ground for one or more of the power domains. FIG. 9B shows the top view of FIG. 9A without the bi-directional ground routing structures 910-1, 910-2, and 910-3, and FIG. 9C shows the top view of FIG. 9A without the bi-directional power routing structures 915-1, 915-2, 915-3, 920-1, 920-2, 920-3, and 925.

In the example shown in FIG. 9A the bi-directional power routing structures 915-1915-2 915-3 920-1 920-2920-3 and 925 include fingers and the bi-directional ground routing structures 910-1 910-2 and 910-3 include fingers in which the fingers of the bi-directional power routing structures 915-1 915-2 915-3 920-1 920-2 920-3 and 925 are interleaved ie interdigitated with the fingers of the bi-directional ground routing structures 910-1 910-2 and 910-3.

For example in the example shown in FIG. 9A the bi-directional ground routing structure 910-1 includes a first elongated member 930 extending in the x direction first fingers 942 extending from the first elongated member 930 in the y direction and second fingers 932 extending from the first elongated member 930 in the y direction The first fingers 942 and the second fingers 932 extend from opposite sides of the first elongated member 930 in this example.

The bi-directional power routing structure 915-2 for the first power domain includes a second elongated member 940 extending in the x direction and third fingers 944 extending from the second elongated member 940 in the y direction In this example the third fingers 944 are interleaved ie interdigitated with the first fingers 942 of the bi-directional ground routing structure 910-1

The bi-directional power routing structure 920-2 for the second power domain includes a third elongated member 936 extending in the x direction and fourth fingers 934 extending from the third elongated member 936 in the y direction In this example the fourth fingers 934 are interleaved ie interdigitated with the second fingers 932 of the bi-directional ground routing structure 910-1.

FIG. 9D shows a top view of an exemplary layout of power bumps for the bi-directional power routing structures 915-1 915-2 915-3920-1920-2 920-3 and 925 and ground bumps for the bi-directional ground routing structures 910-1 910-2 and 910-3 In FIG. 9D each of the power bumps is shown with a dotted line and each of the ground bumps is shown with a dashed line Each of the power bumps and each of the ground bumps may be an instance of one of the bumps 210-1 and 210-2 shown in FIG. 2.

In FIG. 9D the power bumps overlapping the bi-directional power routing structures 915-1 915-2 and 915-3 for the first power domain are coupled to the bi-directional power routing structures 915-1 915-2 and 915-3 and are configured to provide the first supply voltage VDD1 eg from the power source 410 The power bumps overlapping the bi-directional power routing structures 920-1920-2 and 920-3 for the second power domain are coupled to the bi-directional power routing structures 920-1 920-2 and 920-3 and are configured to provide the second supply voltage VDD2 eg from the power source 410 The power bump overlapping the bi-directional power routing structure 925 for the third power domain is coupled to the bi-directional power routing structure 925 and is configured to provide the third supply voltage VDD3 eg from the power source In this example the power source 410 may include multiple voltage regulators where each of the voltages regulators is configured to provide a respective one of the supply voltages

The ground bumps overlapping the bi-directional ground routing structures 910-1 910-2 and 910-3 are coupled to the bi-directional ground routing structures 910-1 910-2 and 910-3 The ground bumps may be coupled to an external ground.

FIG. 9E shows a close-up view of the bi-directional power routing structures 915-1, 915-2, 920-1, and 920-2 and the bi-directional ground routing structures 910-1 and 910-2.

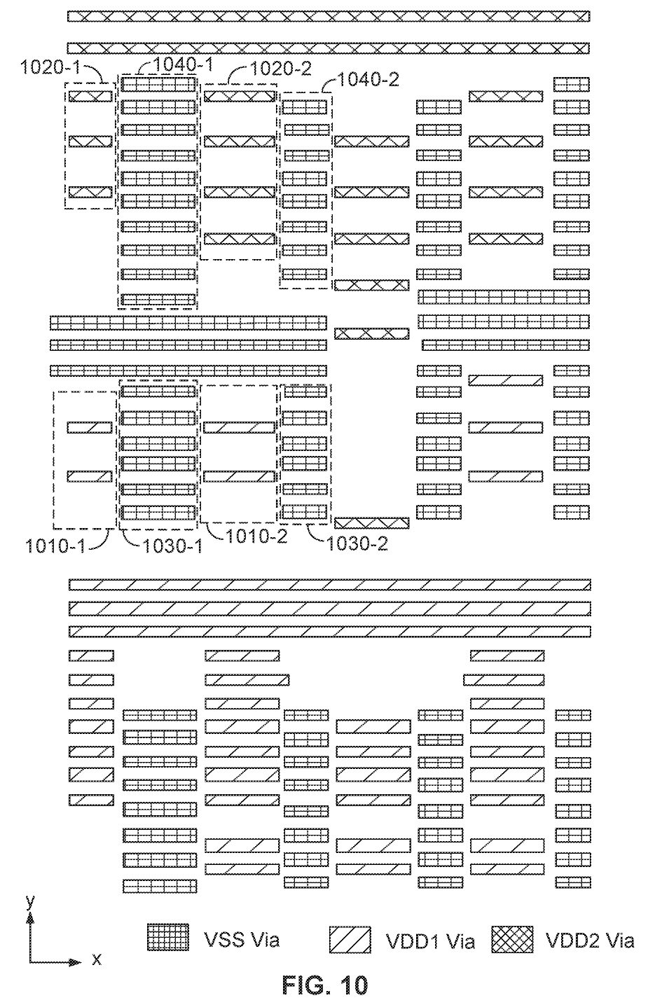

FIG. 10 shows an exemplary layout of power vias and ground vias corresponding to the portion of the bi-directional power routing structures 915-2 and 920-2 and the bi-directional ground routing structures 910-1 and 910-2 enclosed by the box 960 in FIG. 9E. The power vias and the ground vias are disposed between the RDL and the metal layer Mn (e.g., RV vias in FIG. 2). In FIG. 10, the ground vias are labeled VSS, the power vias for the first power domain are labeled VDD1, and the power vias for the second power domain are labeled VDD2.

In this example, the power vias include power vias 1010-1 and 1010-2 under the third fingers 944 (shown in FIG. 9E) of the bi-directional power routing structure 915-2. The power vias 1010-1 and 1010-2 are used to couple the third fingers 944 to power rails for the first power domain in the metal layer Mn. The power vias also include power vias 1020-1 and 1020-2 under the fourth fingers 934 (shown in FIG. 9E) of the bi-directional power routing structure 920-2. The power vias 1010-1 and 1010-2 are used to couple the fourth fingers 934 to power rails for the second power domain in the metal layer Mn.

Also, in this example, the ground vias include ground vias 1030-1 and 1030-2 under the first fingers 942 (shown in FIG. 9E) of the bi-directional ground routing structure 910-1. The ground vias 1030-1 and 1030-2 are used to couple the first fingers 942 to ground rails in the metal layer Mn. The ground vias also include ground vias 1040-1 and 1040-2 under the second fingers 932 (shown in FIG. 9E) of the bi-directional ground routing structure 910-1. The ground vias 1040-1 and 1040-2 are used to couple the second fingers 932 to ground rails in the metal layer Mn.

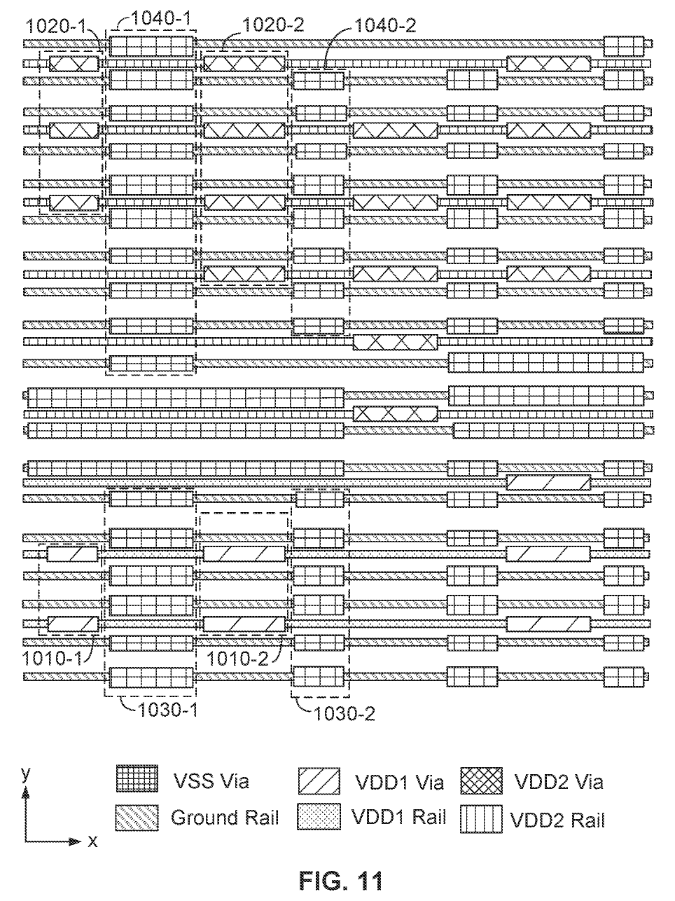

FIG. 11 shows an example of power rials in the metal layer Mn corresponding to the power vias 1010-1, 1010-2, 1020-1, and 1020-2. The power rails corresponding to the first power rails are labeled VDD1 and the power rails corresponding the second power domain are labeled VDD2. In this example, the power rials are unidirectional and extend in the x direction. However, it is to be appreciated that the present disclosure is not limited to this example. In this example, the power vias 1010-1 and 1010-2 are disposed between the third fingers 944 and one or more of the power rails for the first power domain, and the power vias 1020-1 and 1020-2 are disposed between the fourth fingers 934 and one or more of the power rails for the second power domain.

FIG. 11 shows an example of ground rials in the metal layer Mn corresponding to the ground vias 1030-1, 1030-2, 1040-1, and 1040-2. In this example, the ground rails are unidirectional and extend in the x direction. However, it is to be appreciated that the present disclosure is not limited to this example. In this example, the ground vias 1030-1 and 1030-2 are disposed between the first fingers 942 and one or more of the ground rails, and the ground vias 1040-1 and 1040-2 are disposed between the second fingers 932 and one or more of the ground rails.

It is to be appreciated that the power rails and the ground rails may be wider in the y direction that shown in the example in FIG. 11. It is also to be appreciated that the metal layer Mn may include additional power rails and ground rails. In some implementations, the layout may include a power rail and a ground rail in the same row in which the power rail extends in the x direction across a first portion of the row and the ground rail extends in the x direction across a second portion of the row. Also, in some implementations, the layout may include power rails in different power domains occupying different portions of the same row. Accordingly, it is to be appreciated that the present disclosure is not limited to a particular layout of power rails and ground rails.

Implementation examples are described in the following numbered clauses:

1. A chip, comprising:

a bi-directional power routing structure in a redistribution layer, wherein the bi-directional power routing structure comprises:

a first elongated member extending in a first direction;

a second elongated member extending from the first elongated member in a second direction perpendicular to the first direction; and

first fingers extending from the second elongated member in the first direction; and

a bi-directional ground routing structure in the redistribution layer, wherein the bi-directional ground routing structure comprises:

a third elongated member extending in the first direction;

a fourth elongated member extending from the third elongated member in the second direction; and

second fingers extending from the fourth elongated member in the first direction, wherein the second fingers are interleaved with the first fingers.

2. The chip of clause 1, further comprising power bumps coupled to the first elongated member.

3. The chip of clause 2, wherein the power bumps are aligned in the second direction, and each of the power bumps overlaps the first elongated member.

4. The chip of any one of clauses 1to 3, further comprising ground bumps coupled to the third elongated member.

5. The chip of clause 4, wherein the ground bumps are aligned in the second direction, and each of the ground bumps overlaps the third elongated member.

6. The chip of any one of clauses 1to 5, further comprising:

one or more power rails in a metal layer below the redistribution layer; and

first vias disposed between the first fingers and the one or more power rails.

7. The chip of clause 6, wherein each of the one or more power rails extends in the second direction.

8. The chip of clause 6 or 7, further comprising:

one or more ground rails in the metal layer; and

second vias disposed between the second fingers and the one or more ground rails.

9. The chip of clause 8, wherein each of the one or more power rails extends in the second direction, and each of the one or more ground rails extends in the second direction.

10. The chip of clause 8 or 9, wherein the first vias are staggered with respect to the second vias in the first direction.

11. A chip, comprising:

a bi-directional ground routing structure in a redistribution layer, wherein the bi-directional ground routing structure comprises:

a first elongated member;

first fingers extending from the first elongated member in a first direction, wherein the first elongated member extends in a second direction perpendicular to the first direction; and

second fingers extending from the first elongated member in the first direction;

a first bi-directional power routing structure in the redistribution layer, wherein the first bi-directional power routing structure comprises:

a second elongated member extending in the second direction; and

third fingers extending from the second elongated member in the first direction, wherein the third fingers are interleaved with the first fingers; and

a second bi-directional power routing structure in the redistribution layer, wherein the second bi-directional power routing structure comprises:

a third elongated member extending in the second direction; and

fourth fingers extending from the third elongated member in the first direction, wherein the fourth fingers are interleaved with the second fingers.

12. The chip of clause 11, wherein the first bi-directional power routing structure is in a first power domain, and the second bi-directional power routing structure is in a second power domain.

13. The chip of clause 11 or 12, further comprising:

one or more first power bumps coupled to the first bi-directional power routing structure, wherein the one or more first power bumps are configured to provide a first supply voltage; and

one or more second power bumps coupled to the second bi-directional power routing structure, wherein the one or more second power bumps are configured to provide a second supply voltage.

14. The chip of clause 13, wherein the one or more first power bumps overlap the first bi-directional power routing structure, and the one or more second power bumps overlap the second bi-directional power routing structure.

15. The chip of clause 14, further comprising one or more ground bumps coupled to and overlapping the bi-directional ground routing structure.

16. The chip of any one of clauses 11to 15, further comprising:

one or more first power rails in a metal layer below the redistribution layer;

first vias disposed between the third fingers and the one or more first power rails;

one or more second power rails in the metal layer; and

second vias disposed between the fourth fingers and the one or more second power rails.

17. The chip of clause 16, wherein the one or more first power rails are in a first power domain, and the one or more second power rails are in a second power domain.

18. The chip of clause 16 or 17, wherein each of the one or more first power rails extends in the second direction, and each of the one or more second power rails extends in the second direction.

19. The chip of any one of clauses 16to 18, further comprising:

one or more ground rails in the metal layer; and

third vias disposed between the first fingers and the one or more ground rails.

20. The chip of clause 19, wherein each of the one or more first power rails extends in the second direction, each of the one or more ground rails extends in the second direction, and the first vias are staggered with respect to the third vias in the first direction.

21. The chip of any one of clauses 11to 20, wherein the first fingers and the second fingers extend from opposite sides of the first elongated member.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a bi-directional power routing structure in a redistribution layer, wherein the bi-directional power routing structure comprises:
a first elongated member extending in a first direction;
a second elongated member extending from the first elongated member in a second direction perpendicular to the first direction; and
first fingers extending from the second elongated member in the first direction; and
a bi-directional ground routing structure in the redistribution layer, wherein the bi-directional ground routing structure comprises:
a third elongated member extending in the first direction;
a fourth elongated member extending from the third elongated member in the second direction; and
second fingers extending from the fourth elongated member in the first direction, wherein the second fingers are interleaved with the first fingers.

2. The chip of claim 1, further comprising power bumps coupled to the first elongated member.

3. The chip of claim 2, wherein the power bumps are aligned in the second direction, and each of the power bumps overlaps the first elongated member.

4. The chip of claim 1, further comprising ground bumps coupled to the third elongated member.

5. The chip of claim 4, wherein the ground bumps are aligned in the second direction, and each of the ground bumps overlaps the third elongated member.

6. The chip of claim 1, further comprising:
one or more power rails in a metal layer below the redistribution layer; and
first vias disposed between the first fingers and the one or more power rails.

7. The chip of claim 6, wherein each of the one or more power rails extends in the second direction.

8. The chip of claim 6, further comprising:
one or more ground rails in the metal layer; and
second vias disposed between the second fingers and the one or more ground rails.

9. The chip of claim 8, wherein each of the one or more power rails extends in the second direction, and each of the one or more ground rails extends in the second direction.

10. The chip of claim 8, wherein the first vias are staggered with respect to the second vias in the first direction.

11. A chip, comprising:
a bi-directional ground routing structure in a redistribution layer, wherein the bi-directional ground routing structure comprises:
a first elongated member;
first fingers extending from the first elongated member in a first direction, wherein the first elongated member extends in a second direction perpendicular to the first direction; and
second fingers extending from the first elongated member in the first direction;
a first bi-directional power routing structure in the redistribution layer, wherein the first bi-directional power routing structure comprises:
a second elongated member extending in the second direction; and
third fingers extending from the second elongated member in the first direction, wherein the third fingers are interleaved with the first fingers; and
a second bi-directional power routing structure in the redistribution layer, wherein the second bi-directional power routing structure comprises:
a third elongated member extending in the second direction; and
fourth fingers extending from the third elongated member in the first direction, wherein the fourth fingers are interleaved with the second fingers.

12. The chip of claim 11, wherein the first bi-directional power routing structure is in a first power domain, and the second bi-directional power routing structure is in a second power domain.

13. The chip of claim 11, further comprising:
one or more first power bumps coupled to the first bi-directional power routing structure, wherein the one or more first power bumps are configured to provide a first supply voltage; and
one or more second power bumps coupled to the second bi-directional power routing structure, wherein the one or more second power bumps are configured to provide a second supply voltage.

14. The chip of claim 13, wherein the one or more first power bumps overlap the first bi-directional power routing structure, and the one or more second power bumps overlap the second bi-directional power routing structure.

15. The chip of claim 14, further comprising one or more ground bumps coupled to and overlapping the bi-directional ground routing structure.

16. The chip of claim 11, further comprising:
one or more first power rails in a metal layer below the redistribution layer;
first vias disposed between the third fingers and the one or more first power rails;
one or more second power rails in the metal layer; and
second vias disposed between the fourth fingers and the one or more second power rails.

17. The chip of claim 16, wherein the one or more first power rails are in a first power domain, and the one or more second power rails are in a second power domain.

18. The chip of claim 16, wherein each of the one or more first power rails extends in the second direction, and each of the one or more second power rails extends in the second direction.

19. The chip of claim 16, further comprising:
one or more ground rails in the metal layer; and
third vias disposed between the first fingers and the one or more ground rails.

20. The chip of claim 19, wherein each of the one or more first power rails extends in the second direction, each of the one or more ground rails extends in the second direction, and the first vias are staggered with respect to the third vias in the first direction.
